(19) United States
(12) Patent Application Publication
(10) Pub. No.: US 2026/0038705 A1
(43) Pub. Date: Feb. 5, 2026

(54) Isotope Capacitor

(71) Applicant: LG Energy Solution, Ltd., Seoul (KR)

(72) Inventors: Dong Myung Kim, Daejeon (KR); Je Young Kim, Daejeon (KR)

(73) Assignee: LG Energy Solution, Ltd., Seoul (KR)

(21) Appl. No.: 19/286,440

(22) Filed: Jul. 31, 2025

(30) Foreign Application Priority Data
Jul. 31, 2024 (KR) 10-2024-0101654
Jul. 30, 2025 (KR) 10-2025-0103906

(51) Int. Cl. G21H 1/06; H10F 30/295

(52) U.S. Cl. CPC G21H 1/06; H10F 30/2955

(57) ABSTRACT

An isotope capacitor may include a plurality of isotope capacitor sheets that are stacked in a first direction, a first external electrode, and a second external electrode. Each isotope capacitor sheet of the plurality of isotope capacitor sheets includes a substrate including a first material and a second material and a radiation source. The second material may have an electrical conductivity higher than the electrical conductivity of the first material. The second material may be between the first material and the radiation source. The first external electrode and the second external electrode may be configured to transfer electrical energy generated by the plurality of stacked capacitor sheets to an external load.

### CROSS-REFERENCE TO RELATED APPLICATIONS

This application claims priority under 35 U.S.C. § 119 to Korean Patent Applications No. 10-2024-0101654 filed on Jul. 31, 2024, and No. 10-2025-0103906 filed on Jul. 30, 2025, the entire contents of which are incorporated herein by reference.

### TECHNICAL FIELD

The present disclosure relates to an isotope capacitor.

### BACKGROUND

An isotope capacitor is a capacitor that absorbs radiation emitted by radioactive isotopes through the surface of a p-n junction semiconductor and converts the radiation into electrical energy. The radiation generates electron-hole pairs in the space-charge region of the p-n junction semiconductor, and the generated carriers have voltage-current characteristics of an isotope capacitor.

### SUMMARY

### Technical Problem

There is a need for isotope capacitors with improved energy density. Aspects of the present disclosure are directed to isotope capacitors capable of generating electrical energy with increased energy density.

### Technical Solution

To solve the above technical problem, aspects of the present disclosure provide an isotope capacitor including a plurality of isotope capacitor sheets that are stacked in a first direction; and a first external electrode having a first polarity and a second external electrode having a second polarity. Each isotope capacitor sheet of the plurality of isotope capacitor sheets comprises a substrate comprising a first material and a second material and a radiation source. The first material is a non-conductor or a semiconductor. The second material has an electrical conductivity greater than an electrical conductivity of the first material. The substrate comprise an interface between the first material and the second material. The radiation source extends through at least a portion of the substrate in the first direction. The radiation source is spaced apart from the interface between the first material and the second material. The first external electrode is electrically connected to the plurality of isotope capacitor sheets. The second external electrode is connected to the plurality of isotope capacitor sheets, and the first external electrode and the second external electrode are configured to transfer electrical energy generated by the plurality of stacked isotope capacitor sheets to an external load.

Another aspect of the present disclosure provides an isotope capacitor including a plurality of isotope capacitor sheets that are stacked in a first direction, a first external electrode having a first polarity, and a second external electrode having a second polarity. Each isotope capacitor sheet of the plurality of isotope capacitor sheets comprises a substrate comprising a first material and a second material and a radiation source. The radiation source extends through at least a portion of the substrate in the first direction. The first material comprises a semiconductor material, and the second material comprises a metal oxide. The second material has a bandgap that is less than a bandgap of the first material. The second material of the substrate is between the radiation source and the first material of the substrate. The first external electrode is electrically connected to the plurality of isotope capacitor sheets. The second external electrode is electrically connected to the plurality of isotope capacitor sheets, and the first external electrode and the second external electrode are configured to transfer electrical energy generated by the plurality of stacked isotope capacitor sheets to an external load.

### Advantageous Effects

The isotope capacitor of the present disclosure has the effect of generating electric energy with a high energy density.

The effects that may be obtained from the isotope capacitors of the present disclosure are not limited to those mentioned above, and other effects not mentioned may be clearly derived and understood by one of ordinary skill in the art to which the present disclosure belongs from the following description. That is, unintended effects of practicing the present disclosure may also be derived from the aspects of the present disclosure by one of ordinary skill in the art.

### BRIEF DESCRIPTION OF THE DRAWINGS

Aspects of the present disclosure will be more clearly understood from the following detailed description in conjunction with the accompanying drawings in which:

FIGS. 1a and 1b are side cross-sectional views illustrating isotope capacitors according to aspects of the present disclosure.

FIGS. 2a to 2c are plan views of isotope capacitor sheets according to aspects of the present disclosure.

FIGS. 3a and 3b are plan views of isotope capacitor sheets according to aspects of the present disclosure.

FIGS. 4 through 5 are side cross-sectional views of isotope capacitors according to aspects of the present disclosure.

FIG. 6a is a side cross-sectional view of an isotope capacitor according to an aspect of the present disclosure.

FIG. 6b is a plan view of an isotope capacitor sheet according to an aspect of the present disclosure.

FIG. 6c is a side cross-sectional view of an isotope capacitor sheet according to an aspect of the present disclosure.

FIG. 7 is a side cross-sectional view of an isotope capacitor according to an aspect of the present disclosure.

FIG. 8a is a side cross-sectional view of an isotope capacitor according to an aspect of the present disclosure.

FIG. 8b is a perspective view of a first region, a radiation source, and an insulating layer of an isotope capacitor sheet according to an aspect of the present disclosure.

FIG. 9 is a side cross-sectional view of an isotope capacitor according to an aspect of the present disclosure.

FIGS. 10a through 10h are side views illustrating sequential steps of a method of manufacturing an isotope capacitor according to an aspect of the present disclosure.

Like reference numerals and designations refer to the same elements in the figures. Additionally, various elements and areas of the figures are schematically depicted and are not necessarily drawn to scale. Accordingly, the aspects of the present disclosure are not limited to the relative sizes or spacing depicted in the accompanying drawings.

### DETAILED DESCRIPTION

Hereinafter, aspects of the present disclosure will be described in detail with reference to the accompanying drawings. However, the aspects of the present disclosure may be modified in many ways, and it should be understood that the scope of the present disclosure is not limited by the aspects described below. The aspects of the present disclosure are described herein to more fully explain the concepts of the present disclosure to one of ordinary skill in the art.

Terms such as “first,” “second,” and the like may be used to describe various components, but the components are not limited by such terms. These terms are used only for the purpose of distinguishing one component from another and do not imply order, sequence, or total number of components unless the context clearly indicates otherwise. For example, a first component may be named a second component, and vice versa, a second component may be named a first component, without departing from the scope of the present disclosure.

Expressions in the singular include the plural unless the context clearly indicates otherwise. In this application, expressions such as “includes” or “has” are intended to designate the presence of the features, numbers, steps, operations, components, parts, or combinations thereof described, and are not to be understood as precluding the possibility of the presence or addition of one or more other features, numbers, operations, components, parts, or combinations thereof.

Unless otherwise defined, all terms used herein, including technical and scientific terms, shall have the same meaning as commonly understood by one of ordinary skill in the art to which the present disclosure belongs. It is further understood that such terms, as commonly used and as defined in dictionaries, are to be construed to have a meaning consistent with their meaning in the context of the art to which they relate and are not to be construed in an unduly formal sense unless expressly defined herein.

Some aspects of the present disclosure can be implemented differently, and certain processes may be performed in a sequence other than that described. For example, two consecutively described process steps may be performed substantially simultaneously, or in the opposite order from the order described.

In the accompanying drawings, variations in the illustrated shapes may be expected, for example, due to manufacturing techniques and/or tolerances. Accordingly, aspects of the present disclosure should not be construed as limited to the specific shape of the areas shown herein, and should include, for example, variations in shape resulting from manufacturing processes.

The term “and/or” used herein include each and every combination of one or more of the components mentioned. Further, the term “substrate” as used herein may refer to the substrate itself, or to a laminated structure including the substrate and any predetermined layers or films formed on its surface. Further, as used herein, the term “surface of the substrate” may refer to the exposed surface of the substrate itself, or to the outer surface of a predetermined layer or film formed on the substrate.

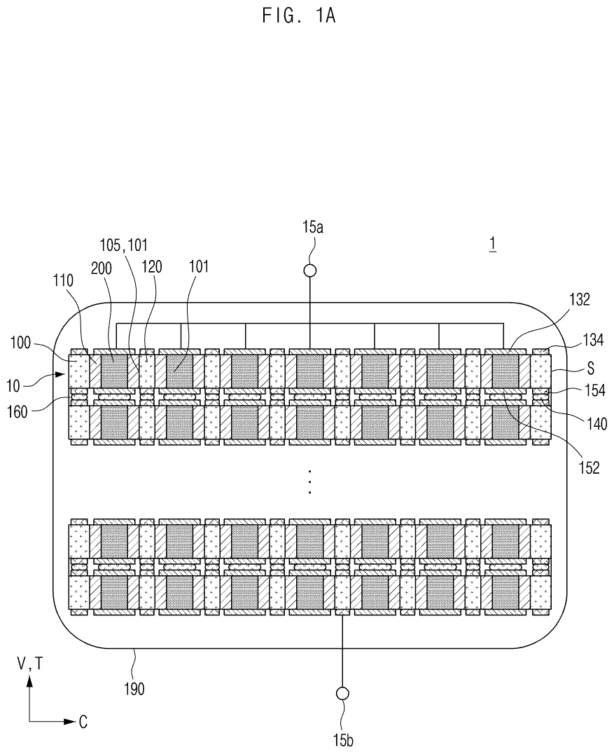

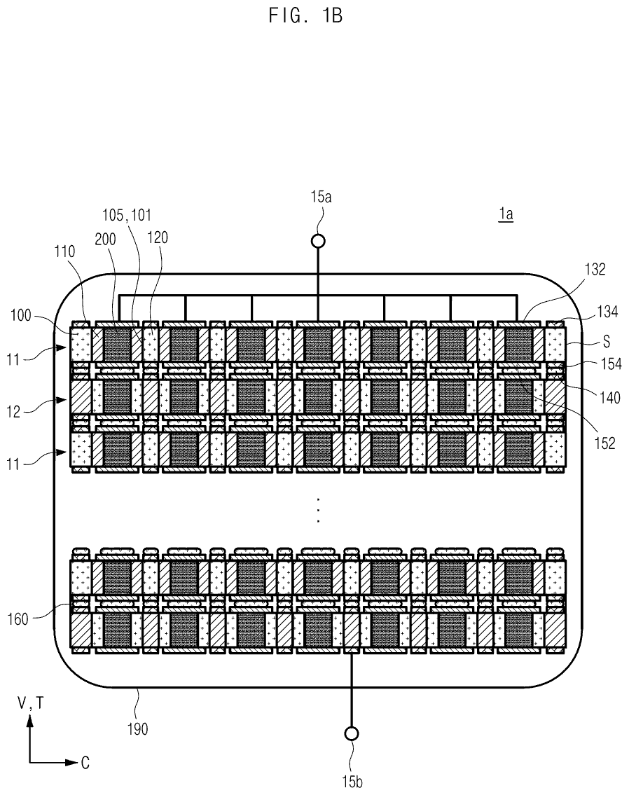

FIG. 1a is a side cross-sectional view illustrating an isotope capacitor 1 according to an aspect of the present disclosure.

Referring to FIG. 1a, the isotope capacitor 1 may include a plurality of isotope capacitor sheets 10 that are stacked on each other to form a layered structure. The plurality of isotope capacitor sheets may be stacked on each other in a vertical direction V, or a substrate thickness direction T. In the aspect depicted in FIG. 1, the vertical direction V may be the same as the substrate thickness direction T. In one or more aspects, the isotope capacitor may comprise greater than or equal to 2 isotope capacitor sheets 10. For example, the number of isotope capacitor sheets 10 may be greater than or equal to 2, 3, 4, 5, 6, 7, 8, 9, 10, 15, 20, 25, or 30.

Each of the plurality of isotope capacitor sheets 10 may include substrate 100 and a radiation source 200.

The substrate 100 may comprise a first surface and a second surface opposite the first surface in the substrate thickness direction T. The first surface and the second surface may be the top and bottom major surfaces of the substrate 100, respectively. A thickness of the substrate refers to an average distance from the first surface of the substrate to the second surface of the substrate in the substrate thickness direction T.

The radiation source 200 may penetrate at least a portion of the substrate 100. In one or more aspects, the radiation source 200 may extend through at least a portion of the substrate 100 in the substrate thickness direction. The radiation source 200 may extend through an entire thickness of the substrate 100. In such aspects, the radiation source 200 may extend from the first surface to the second surface of the substrate 100. In some aspects, the radiation source 200 may extend through a portion of the substrate 100. For example, the radiation source 200 may extend from the first surface of the substrate 100 toward the second surface of the substrate 100 in the substrate thickness direction T. In another example, the radiation source 200 may extend from the second surface of the substrate 100 toward the first surface of the substrate 100 in the substrate thickness direction T.

In one or more aspects, the radiation source 200 may be disposed in a through hole 101 of the substrate 100. The through hole 101 may extend from the first or second surface of the substrate toward the opposite surface of the substrate. The through hole 101 may extend in the substrate thickness direction T. The through hole 101 may have an opening at the first surface of the substrate 100, the second surface of the substrate 100, or both the first surface and the second surface of the substrate 100. In the aspect depicted in FIG. 1a, the through hole 101 extends from the first surface of the substrate 100 to the second surface of the substrate 100 in the substrate thickness direction T and has openings at both the first and second surfaces of the substrate 100.

In one or more aspects, the radiation source 200 may be disposed between the first surface and the second surface of the substrate 100. In such aspects, the space between isotope capacitor sheets 10 in the isotope capacitor 1 may be free from the radiation source.

The substrate 100 may include a first material 120 and a second material 110. The second material 110 may be between the radiation source 200 and the first material 120.

As schematically depicted in FIG. 1a, the second material 110 and the first material 120 may be adjacent to one another. The second material 110 and the first material 120 may be repeatedly and/or alternately disposed in a substrate transverse direction C, which is perpendicular to the substrate thickness direction T. In one or more aspects, an interface between the second material 110 and the first material 120 may extend from the first surface of the substrate 100 to the second surface of the substrate 100. In some aspects, the interface between the second material 110 and the first material 120 may extend in the substrate thickness direction T. The second material 110 and the first material 120 may form a p-n junction at the interface.

The first material 120 may be a non-conductor or a semiconductor. In some aspects, the first material 120 may include a diamond substrate, a SiC substrate, a GaN substrate, a Bi₂O₃/GeO₂ substrate, a Sm₂O₃/Bi₂O₃/GeO₂ substrate, a Sm₂O₃/Bi₂O₃/B₂O₃ substrate, a Sm₂O₃/Bi₂O₃/GeO₂/B₂O₃ substrate, a sapphire substrate, or a combination thereof. In some aspects, the first material 120 may be undoped. An undoped material is free or substantially free of dopants. A material is “substantially free” of a dopant when no dopant is intentionally added to the material. In some aspects, the first material 120 may be doped with a dopant.

In some aspects, the first material 120 may have a chemical formula of AMO₃ where A is one or more elements selected from the group consisting of La, Ba, Sr, and K, and M is one or more elements selected from the group consisting of Al, In, Ga, Ti, Sn, Hf, Ta, and Zr.

In one or more aspects, the first material 120 may comprise one or more of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, or LaAlO₃ (where 0<x<1).

In some aspects, the first material 120 may include a semiconductor material. In some aspects, the first material 120 may include an insulating substrate.

In some aspects, the second material 110 may include a metal oxide having a bandgap energy of 2.7 eV or greater. In some aspects, the metal oxide may have the formula AMO₃ where A is one or more elements selected from the group consisting of La, Ba, Sr, and K, and M is one or more elements selected from the group consisting of Al, In, Ga, Ti, Sn, Hf, Ta, and Zr.

In one or more aspects, the metal oxides in the second material 110 may include one or more of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, or LaAlO₃ (where 0<x<1).

The metal oxides are not only stable in high temperature and high humidity environments, but also have a high mobility of carriers, which allows them to efficiently absorb radiation emitted from the radiation source 200 and/or photons emitted from the photon generating layer 250 described later, thereby providing a high energy conversion efficiency. In addition, there is no inelastic collision in carrier transport, which is advantageous for energy loss and heat dissipation. For example, the metal oxide may have a carrier mobility of greater than or equal to 45 cm²/(V·s), greater than or equal to 80 cm²/(V·s), greater than or equal to 120 cm²/(V·s), or even greater than or equal to 300 cm²/(V·s).

These metal oxides are materials that can be doped in any conductivity type and have the advantage of being able to provide high current or high voltage depending on the direction of the applied bias.

Still referring to FIG. 1a, the second material 110 and the first material 120 of the substrate 100 can generate electron-hole pairs from radiation emitted by the radiation source 200. In some aspects, the second material 110 and the first material 120 of the substrate 100 may comprise an inorganic layer, an organic layer, a dye sensitized layer, or a combination thereof, and the second material 110 and the first material 120 may generate power by forming electron-hole pairs from radiation emitted by the radiation source 200.

The first material 120 includes a doped region comprising a dopant, the doped region may be adjacent to the second material 110.

In one or more aspects, the second material 110 may be doped with a dopant of a first conductive type. The doped region of the first material 120 may be doped with a dopant of the second conductive type. In some aspects, the first conductive dopant may be an n-type dopant and the second conductive dopant may be a p-type dopant. In some other aspects, the dopant of the first conductive type may be a p-type dopant and the dopant of the second conductive type may be an n-type dopant. Depending on the conductivity type of the dopants doped in each region, one of the second material 110 and the first material 120 may act as a cathode and the other may act as an anode. That is, if the dopant of the first conductive type is n-type dopant and the dopant of the second conductive type is p-type dopant, then the second material 110 may act as an anode and the first material 120 may act as a cathode. Conversely, if the dopant of the first conductive type is a p-type dopant and the dopant of the second conductive type is an n-type dopant, the second material 110 can act as a cathode and the first material 120 can act as an anode.

The n-type doped region may be, for example, silicon or diamond doped with nitrogen (N), phosphorus (P), arsenic (As), or antimony (Sb), which are Group 15 elements of the periodic table, or it may be a compound semiconductor doped with nitrogen (N), phosphorus (P), arsenic (As), or antimony (Sb), which are Group 15 elements of the periodic table. As used herein, a compound semiconductor refers to a semiconductor composed of two or more elements, such as silicon carbide, silicon oxide, aluminum phosphide (AlP), aluminum arsenide (AlAs), gallium arsenide (GaAs), or gallium nitride (GaN). In some aspects, the n-type dopants may include silicon (Si), germanium (Ge), or tellurium (Te).

The p-type doped region may be, for example, silicon or diamond doped with any of the Group 13 elements of the periodic table, such as boron (B), aluminum (Al), gallium (Ga), or indium (In), or may be a compound semiconductor doped with any of the boron group elements of the periodic table, such as boron (B), aluminum (Al), gallium (Ga), or indium (In). In some aspects, the p-type dopants may include beryllium (Be), magnesium (Mg), or zinc (Zn).

In some aspects, the second material 110 or the first material 120 or both the second material 110 and the first material 120 may include an organic material. The organic material may be used in organic layers that receive light to generate power, such as in solar cell applications. For example, the second material 110 and the first material 120 may include a thiophene-like compound. In some aspects, the second material 110, the first material 120, or both may be inorganic-organic hybrids, including any suitable mix of inorganic and organic materials described above.

In some aspects, a depletion region may be formed near the interface where the second material 110 and the first material 120 contact each other.

In one or more aspects, the first material 120 may include a concave part. In some aspects, the concave part may be a hole or a trench. The concave part may have an inwardly extending shape between the main surfaces of the substrate 100. The concave part may fully penetrate the first material 120, or may partially penetrate the first material 120.

The second material 110 may form an interface with the first material 120. The second material 110 may be disposed at least partially within the concave part. In some aspects, the second material 110 may be disposed entirely within the concave part.

The second material 110 may be a material with a higher electrical conductivity compared to the first material 120. In some aspects, the second material 110 may include a material having a smaller bandgap than the first material 120. In some aspects, the second material 110 may include a material having a bandgap of about 2.7 eV or greater, about 3.0 eV or greater, or about 3.5 eV or greater.

The radiation source 200 may be located within the substrate 100. In some aspects, the radiation source 200 may be spaced apart from the interface between the first material 120 and the second material 110. In some aspects, the radiation sources 200 may be spaced apart from the first material 120.

In some aspects, the second material 110 may be arranged conformally within the concave part of the first material 120. In such aspects, the second material 110 may have a recessed space shaped similar to the concave part in the first material 120. In some aspects, the radiation source 200 may be disposed within the recessed space in the second material 110.

In some aspects, the radiation source 200 may penetrate the substrate 100. The second material 110 may be interposed between the first material 120 and the radiation source 200. Specifically, the second material 110 may be on a side of the radiation source 200, and the first material 120 may be on a side of the second material layer 110 opposite the radiation source 200.

In some aspects, the radiation source 200 may be positioned within a through-hole 101 penetrating at least a portion of the substrate 100. The through-hole 101 may comprise an opening in the first surface of the substrate 100. In one or more aspects, the radiation source 200 may partially or completely fill the through-hole 101. In some aspects, the radiation source 200 may be in contact with a circumference of the through-hole 101. For example, in some aspects, the radiation source 200 may completely fill a through-hole 101 having a circular cross-sectional shape such that the radiation source 200 has a cylindrical shape. In other aspects, the radiation source 200 may partially fill a through-hole 101 having a circular cross-sectional shape such that the radiation source 200 has an annular shape.

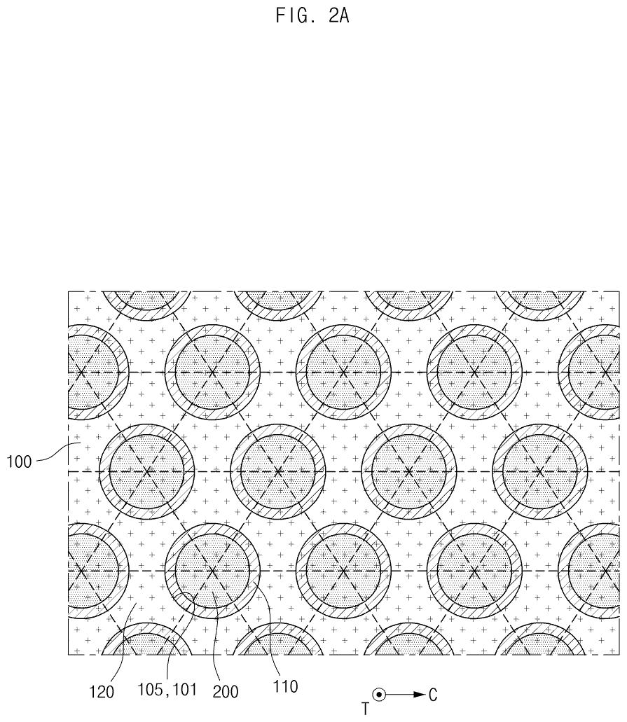

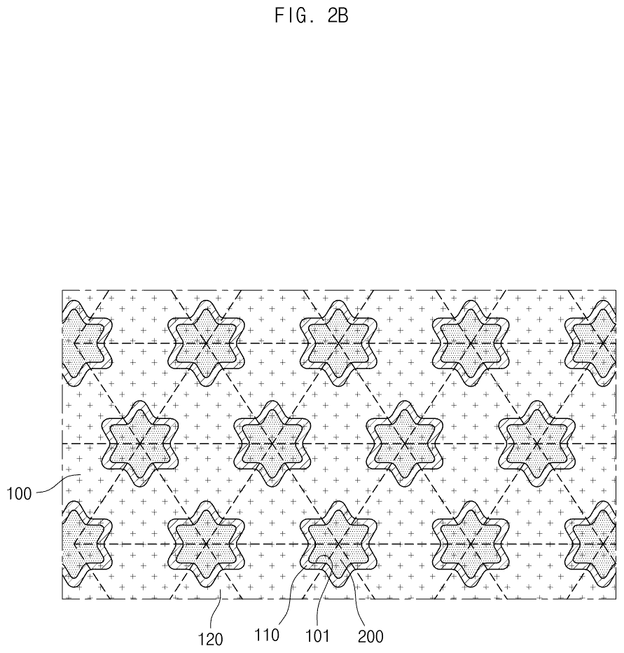

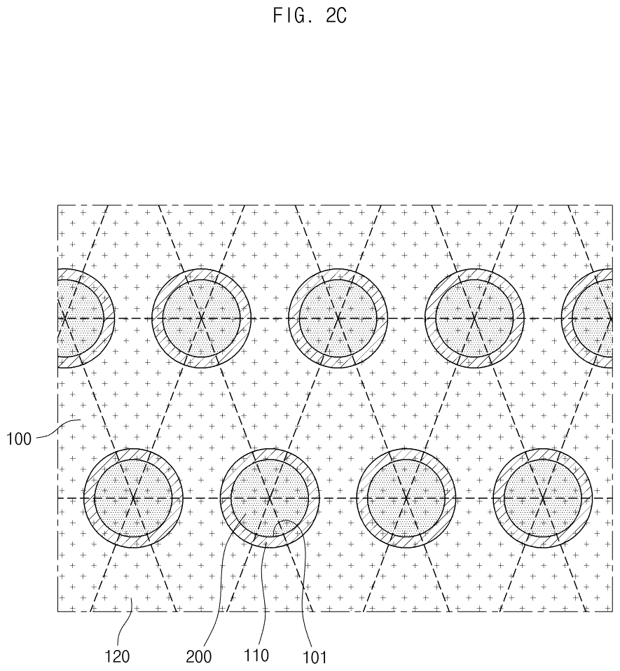

FIGS. 2a to 2c are plan views illustrating configurations in which the radiation source 200 may be disposed in the through-hole 101 according to aspects of the present disclosure.

Referring to FIG. 2a, the substrate 100 is provided with a plurality of through-holes 101 penetrating through the substrate 100, and the radiation source 200 may be disposed within the through-holes 101. The through-holes 101, as shown in FIG. 2a, may have a circular cross-section. However, the cross-sectional shape of the through-holes 101 is not limited to a circle. For example, the through-holes 101 may have a cross-sectional shape of a circle, an oval, an ellipse, a triangle, a rectangle, a pentagon, a hexagon, any regular polygon, any irregular polygon, or any closed shape.

The through-holes 101 may be formed by any method known to those of ordinary skill in the art. For example, the through-holes 101 may be formed by anisotropic etching, isotropic etching, laser irradiation, or the like. In some aspects, the through-holes 101 may be formed by irradiating the substrate 100 with laser light. In some aspects, the through-holes 101 may be formed by reactive ion etching (RIE).

In some aspects, the through-holes 101 may be arranged with a predetermined regularity or pattern. The pattern may be in a plane normal to the vertical direction V. In one or more aspects, the through-holes 101 may be arranged at the vertices of a series of equilateral or isosceles triangles, rectangles, squares, diamonds, trapezoids, or any other suitable shape. In some aspects, the through-holes 101 may be arranged such that gaps between neighboring through-holes 101 are approximately the same size resulting a regular or consistent distribution of radiation source 200 in the isotope capacitor sheet 10.

In some aspects, the through-holes 101 may be arranged so that their respective centers are located at the vertices of a series of imaginary equilateral triangles. By arranging the through-holes 101 so that their centers are located at the vertices of imaginary equilateral triangles, the number of radiation sources 200 that can be accommodated per unit area can be maximized. Therefore, energy density of the isotope capacitor 1 can be increased.

In some aspects, the second material 110 may be disposed to surround a side of the radiation source 200. In some aspects, the first material 120 may be disposed to surround the sides of the second material 110. Referring to FIG. 2a, the second material 110 is in an annular shape to surround each radiation source 200, and the first material 120 surrounds the annular second material 110. In some aspects, the second material 110 may include one type of material, and the first material 120 may include another type of material.

Referring to FIG. 2b, the sidewalls of the through-holes 101 may have irregularities. That is, the through-holes 101 may have concave and convex portions. The interface of the radiation source 200 and the second material 110 may have irregularities. In some aspects, the interface of the second material 110 and the first material 120 may have irregularities.

The second material 110 may have a substantially constant lateral thickness, as shown in FIG. 2b. Accordingly, the interface of the second material 110 and the first material 120 may have a shape corresponding to the interface of the radiation source 200 and the second material 110.

The side walls of the through-holes 101 may have irregularities, thereby increasing the contact area between the radiation source 200 and the second material 110. Additionally, the interface between the second material 110 and the first material 120 may have a corrugated shape, which increases the contact area between the second material 110 and the first material 120, thereby improving the efficiency of the isotope capacitor 1. As an example, the irregularities illustrated in FIG. 2b may be in the form of repeating corrugations extending linearly along the vertical direction V or the thickness direction T.

Referring to FIG. 2c, each center of the through-holes 101 may be arranged to be located at the vertex of a series of imaginary isosceles triangles. As shown in FIG. 2a, the centers of the through-holes 101 need not necessarily be located at the vertices of a series of virtual equilateral triangles.

In some aspects, the triangles in which the respective centers of the through-holes 101 are disposed may be triangles having some different shapes. Accordingly, the through-holes 101 may be somewhat irregularly arranged.

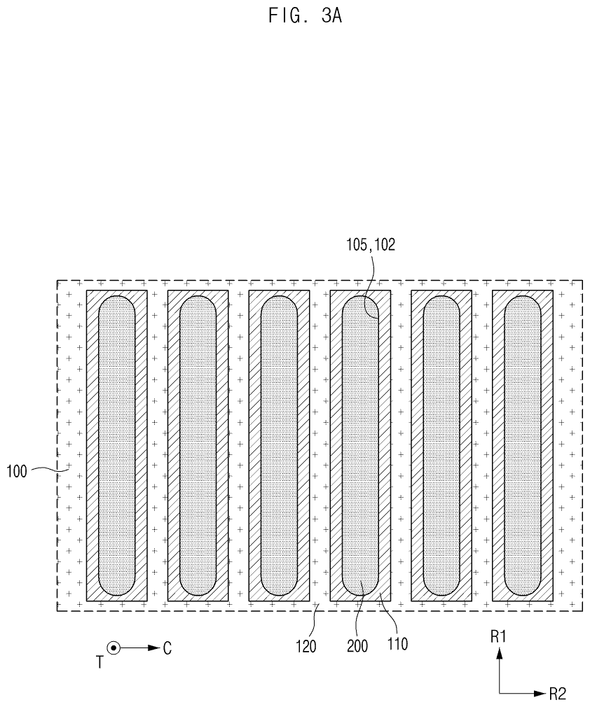

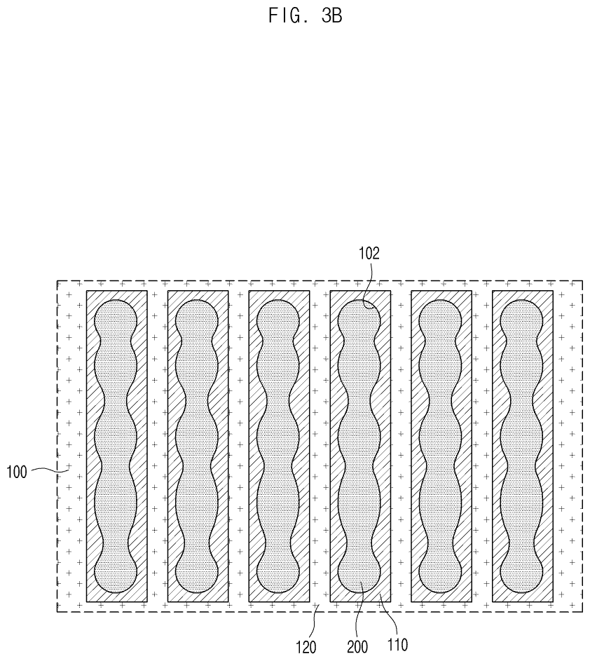

In some aspects, the radiation source 200 may be disposed within a slit extending into the substrate 100. FIGS. 3a and 3b are plan views illustrating configurations in which the radiation source 200 may be disposed in the slit 102 according to aspects of the present disclosure.

Referring to FIG. 3a, the substrate 100 may include a plurality of slits 102 extending in parallel in a first direction R1. Each of the plurality of slits 102 may be elongated in a second direction R2 that is perpendicular to the first direction R1. The first direction R1 and the second direction R2 are perpendicular to the substrate thickness direction T. Further, a radiation source 200 may be provided within each of the plurality of slits 102. As shown in FIG. 3a, the slits 102 may have a length in the first direction R1 that is greater than a width of the slit 102 in the second direction R2.

In some aspects, a side of the radiation source 200 may contact a side of each of the plurality of slits 102. The radiation source 200 may be in contact with a perimeter of each of the plurality of slits 102.

In some aspects, the second material 110 may face an extended side of the radiation source 200. The second material 110 may face both extended sides of the radiation source 200. For example, the second material 110 may extend along two longitudinal sides of the slit 102 extending in the first direction R1. As exemplarily shown in FIG. 3a, the second material 110 may completely surround the slit 102. In one or more aspects, the second material 110 may be disposed to completely or at least partially surround the radiation source 200.

In some aspects, the first material 120 may be disposed to face an extended side of the second material 110. For example, the first material 120 may extend along the part of the second material 110 which extends along the longitudinal side of the slit 102.

In some aspects, the second material 110 may be disposed to surround the sides of the radiation source 200. In some aspects, the first material 120 may be disposed to surround the sides of the second material 110 at least partially. In some aspects, as shown in FIG. 3a, the first material 120 may completely surround the second material 110.

Referring to FIG. 3b, the side walls of the slits 102 may have irregularities. That is, the side walls of the slits 102 may have concave and convex portions. The interface of the radiation source 200 and the second material 110 may have irregularities.

When the side walls of the slits 102 have irregularities, the contact area between the radiation source 200 and the second material 110 may be increased, thereby improving the efficiency of the radiation source 200. Thus, as an example, the irregularities illustrated in FIG. 3b may be in the form of repeating corrugations extending linearly along the vertical direction V or the thickness direction T.

In FIG. 1a through FIG. 3b, the entirety of the first material 120 is shown as doped region, but aspects the present disclosure are not limited to this configuration. In FIG. 1a through FIG. 3b, regions of different conductivity or dopant concentrations may be present in the interior of the first material 120, or regions may be present that are not doped with a particular conductivity. In some aspects, the first material 120 may not be doped with dopants. In this case, the first material 120 may be an electrical non-conductor.

Referring again to FIG. 1a, each isotope capacitor sheet of the plurality of isotope capacitor sheets 10 may be substantially identical. For example, each isotope capacitor sheet may have an identical semiconductor die. Each isotope capacitor sheet of the plurality of isotope capacitor sheets 10 may include a first upper electrode 132 at an upper part of the second material 110 and a first lower electrode 152 at the lower part of the second material 110. In one or more aspects, the first upper electrode 132 may be in electrical contact with the second material 110 at the first surface of the substrate 100, and the first lower electrode 152 may be in contact with the second material 110 at the second surface of the substrate 100.

Further, each of the isotope capacitor sheets 10 may include a second upper electrode 134 at the upper part of the first material 120 and a second lower electrode 154 at the lower part of the first material 120. In one or more aspects, the second upper electrode 134 may be in electrical contact with the first material 120 at the first surface of the substrate 100, and the second lower electrode 154 may be in contact with the first material 120 at the second surface of the substrate 100.

In some aspects, a top-most isotope capacitor sheet 10 may comprise the first upper electrode 132 and may be free from the second upper electrode 134. In some aspects the top-most isotope capacitor sheet 10 may comprise the second upper electrode 134 and be free from the first upper electrode 132. In some aspects, a bottom-most isotope capacitor sheet 10 may comprise the first lower electrode 152 and may be free from the second lower electrode 154. In some aspects, the bottom-most isotope capacitor sheet 10 may comprise the second lower electrode 154 and may be free from the first lower electrode 152. In one or more aspects, a portion of the second material 110 or the first material 120 or both which lacks an electrode may be in contact with a passivation layer.

Each of the first upper electrode 132, the first lower electrode 152, the second upper electrode 134, and the second lower electrode 154 may act as a current collector. Each of the first upper electrode 132, the first lower electrode 152, the second upper electrode 134, and the second lower electrode 154 is not particularly limited in type, size, and shape as long as it is electrically conductive without causing physical and chemical changes to the isotope capacitor sheet 10. For example, each of the first upper electrode 132, the first lower electrode 152, the second upper electrode 134, and the second lower electrode 154 may be cylindrical, tetrahedral, hexahedral, torus, or pad-shaped. In some aspects, each of the first upper electrode 132, the first lower electrode 152, the second upper electrode 134, and the second lower electrode 154 may have a hollow center portion. In some aspects, at the first surface of the substrate 100, the second upper electrode 134 may be a continuous layer comprising openings arranged corresponding to the second material 110, and the first upper electrodes 132 may be positioned in said openings. In some aspects, at the second surface of the substrate 100, the second lower electrode 154 may be a continuous layer comprising openings arranged corresponding to the second material 110, and the first lower electrodes 152 may be positioned in said openings.

In some aspects, each of the first upper electrode 132, the first lower electrode 152, the second upper electrode 134, and the second lower electrode 154 may include a metallic material, a transparent oxide, or a carbon-based compound. The metallic material may comprise gold (Au), silver (Ag), platinum (Pt), stainless steel, copper (Cu), aluminum (Al), nickel (Ni), or titanium (Ti). the transparent oxide may include fluorine (F)-doped tin oxide (FTO) or indium tin oxide (ITO, In₂O₃). the carbon-based compound may include carbon-nanotubes, graphene, or graphene oxide.

In some aspects, the radiation source 200 may include a radioactive isotope that emits beta rays. Radioactive isotopes are not limited as long as they decay and emit beta rays, but may include one or more of tritium (³H), calcium-45 (⁴⁵Ca), nickel-63 (⁶³Ni), copper-67 (⁶⁷Cu), strontium-90 (⁹⁰Sr), promethium-147 (¹⁴⁷Pm), osmium-194 (¹⁹⁴OS), thulium-171 (¹⁷¹Tm), tantalum-182 (¹⁸²Ta), cadmium-115 (¹¹⁵Cd), germanium-75 (⁷⁵Ge), cerium-141 (¹⁴¹Ce), cerium-144 (¹⁴⁴Ce), or tungsten-185 (¹⁸⁵W). However, aspects of the present disclosure are not limited to these. In one or more aspects the radioactive isotope may emit only beta rays, or it may emit beta rays, including alpha rays, gamma rays, or the like.

In some aspects, the radiation source 200 may include a radioactive isotope that emits alpha rays. For example, the radiation source 200 may include one or more of americium-241 (²⁴¹Am), americium-243 (²⁴³Am), polonium-209 (²⁰⁹Po), polonium-210 (²¹⁰Po), plutonium-238 (²³⁸Pu), plutonium-239 (²³⁹Pu), curium-242 (²⁴²Cm), curium-244 (²⁴⁴Cm), curium-249 (²⁴⁹Cm), promethium-147 (¹⁴⁷Pm), uranium-238 (²³⁸U), thorium-232 (²³²Th), radium-226 (²²⁶Ra), bismuth-210 (²¹⁰Bi), neptunium-237 (²³⁷Np), europium-152 (¹⁵²Eu), francium-223 (²²³Fr), astatine-210 (²¹⁰At), protactinium-231 (²³¹Pa), einsteinium-253 (²⁵³Es), californium-252 (²⁵²⁰Cf), or berkelium-249 (²⁴⁹Bk). However, aspects of the present disclosure are not limited to these.

The radiation source 200 may be formed by any suitable method known to those skilled in the art. For example, the radiation source 200 may be formed by various methods such as plating, vapor deposition, atomic layer deposition (ALD), etc.

In some aspects, the radiation source 200 may be formed by plating. When the radiation source 200 is formed by plating, a seed layer may be formed, followed by electroplating to form the radiation source 200. In some aspects, the radiation source 200 may be formed by electroless plating.

The first lower electrode 152 of an isotope capacitor sheet 10 may be electrically connected to the first upper electrode 132 of an adjacent, lower isotope capacitor sheet 10. In some aspects, the first lower electrode 152 of an isotope capacitor sheet 10 and the first upper electrode 132 of the adjacent, lower isotope capacitor sheet 10 may be connected by a connector 140, such as a solder ball.

In one or more aspects, the second lower electrode 154 of an isotope capacitor sheet 10 may be electrically connected to the second upper electrode 134 of an adjacent, lower isotope capacitor sheet 10. In some aspects, the second lower electrode 154 of the isotope capacitor sheet 10 and the second upper electrode 134 of the adjacent, lower isotope capacitor sheet 10 may be connected by a connector 140, such as a solder ball.

In some aspects, the connector 140 may include a conductive material. The conductive material may include one or more of tin (Sn), indium (In), bismuth (Bi), antimony (Sb), copper (Cu), silver (Ag), zinc (Zn), or lead (Pb). The number, spacing, arrangement, and shape of the connectors 140 may be varied by design without limitation to those shown. Referring to FIGS. 1a and 1b, the connector 140 may have the form of a solder ball or a solder bump.

In some aspects, a first type of connector may connect the first lower electrode 152 of an isotope capacitor sheet 10 and a first upper electrode 132 of an adjacent, lower isotope capacitor sheet 10, and a second type of connector may connect the second lower electrode 154 of the isotope capacitor sheet 10 and a second upper electrode 134 of the adjacent, lower isotope capacitor sheet 10. In some aspects, the first type of connector and the second type of connector may have different shapes or different sizes. In some aspects, the first type of connector and the second type of connector may comprise the same material or different materials.

The space between the two vertically neighboring isotope capacitor sheets 10 may be filled by an insulator 160. The insulator 160 is not limited as long as it is any material having electrically insulating properties. For example, the insulator may include one or more of a silicate (e.g., TEOS), silicon nitride (SiN), hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, barium titanium oxide, strontium titanium oxide, yttrium oxide, or aluminum oxide. In some aspects, the insulator 160 may include one or more of strontium titanium oxide, yttrium oxide, or aluminum oxide. In some aspects, the insulator 160 may comprise a passivation layer.

The isotope capacitor 1 shown in FIG. 1a can be obtained by manufacturing individual isotope capacitor sheets 10 and then stacking them. By manufacturing individual isotope capacitor sheets 10 and then stacking them, defective isotope capacitor sheets 10 can be selectively excluded from the stacking process, thereby improving the manufacturing yield of the isotope capacitor 1 and reducing manufacturing costs.

The plurality of isotope capacitor sheets 10 may be housed within a housing 190. The plurality of isotope capacitor sheets 10 may be electrically connected to an external load by conductors drawn outside through the housing 190. For example, first outer electrode 15a and second outer electrode 15b may electrically connect the plurality of isotope capacitor sheets 10 to an external load.

In some aspects, the housing 190 may further include an electromagnetic interference (EMI) shield (not shown) capable of shielding electromagnetic waves from entering or exiting the housing 190. The EMI shield may be formed on at least a portion of an inner surface and/or an outer surface of the housing 190. The EMI shield may include, for example, a metal such as copper, or aluminum, a conductive polymer such as polyaniline, or a magnetic material such as iron oxide. The EMI shield may be a sheet, mesh, applied layer, spray coating, non-woven fabric, tape, or fabric layer. By providing the EMI shield on the housing 190, the electromagnetic compatibility (EMC) of the stack-type capacitor 1 can be ensured. In addition, in some aspects, the EMI shield can prevent or otherwise restrict beta rays or other radiation (e.g., alpha rays or gamma rays) from exiting the housing 190.

Referring again to FIG. 1a, the first upper electrodes 132 of the isotope capacitor sheet 10 may be electrically connected to each other and electrically connected to a first outer electrode 15a of a first polarity. Further, the second lower electrodes 154 of the lowest isotope capacitor sheet 10 may be electrically connected to a second outer electrode 15b of a second polarity. The first outer electrode 15a and second outer electrode 15b may be exposed to the outside of the housing 190 for connection to an external load.

In some aspects, the second lower electrodes 154 of the isotope capacitor sheet 10 disposed at the lowest part in FIG. 1 may be electrically connected to each other by surrounding the first lower electrode 152 of the second surface of the substrate 100. In some aspects, the second lower electrodes 154 may be electrically connected to each other by separate conductive lines (not shown) and to the second outer electrode 15b exposed outside the housing 190. The external load may include one or more of an electronic device, an electro-chemical battery, an energy storage devise or any other suitable device. In the aspect of the present disclosure depicted in FIG. 1a, the p-n junctions included in the plurality of isotope capacitor sheets 10 are connected in parallel such that the output electrical current flowing through the first outer electrode 15a and the second outer electrode 15b is a sum of the individual currents of each p-n junction in each of the plurality of isotope capacitor sheets 10.

FIG. 1b is a side cross-sectional view of an isotope capacitor 1a according to another aspect of the present disclosure.

Referring to FIG. 1b, the isotope capacitor 1a may have a first isotope capacitor sheet 11 and a second isotope capacitor sheet 12 alternately and repeatedly stacked. The number of first isotope capacitor sheets 11 included in the isotope capacitor 1a is not necessarily limited. For example, the isotope capacitor 1a may comprise at least 2, 3, 4, 5, 6, 7, 8, 9, or 10 of the first isotope capacitor sheets 11. Likewise, the number of second isotope capacitor sheets 12 included in the isotope capacitor 1a is not necessarily limited. For example, the isotope capacitor 1a may comprise at least 2, 3, 4, 5, 6, 7, 8, 9, or 10 of the second isotope capacitor sheets 12. In some aspects, the uppermost capacitor sheet of the isotope capacitor 1a may be a first isotope capacitor sheet 11. In some aspects, uppermost capacitor sheet of the isotope capacitor 1a may be a second isotope capacitor sheet 12. In some aspects, a lowermost capacitor sheet of the isotope capacitor 1a may be a first isotope capacitor sheet 11. In some aspects, a lowermost capacitor sheet of the isotope capacitor 1a may be a first isotope capacitor sheet 12. The uppermost and lowermost capacitor sheets of the isotope capacitor 1a may be the same or different, provided that the first isotope capacitor sheets 11 and the second isotope capacitor sheets are alternately stacked in the isotope capacitor 1a.

The first isotope capacitor sheet 11 is substantially the same as the isotope capacitor sheet 10 described with reference to FIG. 1a, and therefore will not be described in detail here.

The second isotope capacitor sheet 12 is substantially identical to each component of the first isotope capacitor sheet 11, but differs in that the conductivity of the dopants is reversed. That is, if the second material 110 of the first isotope capacitor sheet 11 is p-type doped, the second material 110 of the second isotope capacitor sheet 12 may be n-type doped. Conversely, if the second material 110 of the first isotope capacitor sheet 11 is n-type doped, the second material 110 of the second isotope capacitor sheet 12 may be p-type doped.

Similarly, if the first material 120 of the first isotope capacitor sheet 11 is p-type doped, the first material 120 of the second isotope capacitor sheet 12 may be n-type doped. Conversely, if the first material 120 of the first isotope capacitor sheet 11 is n-type doped, the first material 120 of the second isotope capacitor sheet 12 may be p-type doped.

In some aspects, the first material 120 is not doped with dopants, in which case the doping region of the first material 120 may not be present.

The stack-type capacitor 1a shown in FIG. 1b can achieve a higher voltage of electrical energy because the number of unit cells corresponding to individual radiation sources 200 is increased and the individual p-n junctions are connected in series. The first outer contact 15a and the second outer contact 15b can have a higher operating voltage than in the isotope capacitor 1 of FIG. 1a because in FIG. 1b, the p-n junctions are connected in series so that the overall output voltage is the sum of the individual p-n junction voltages.

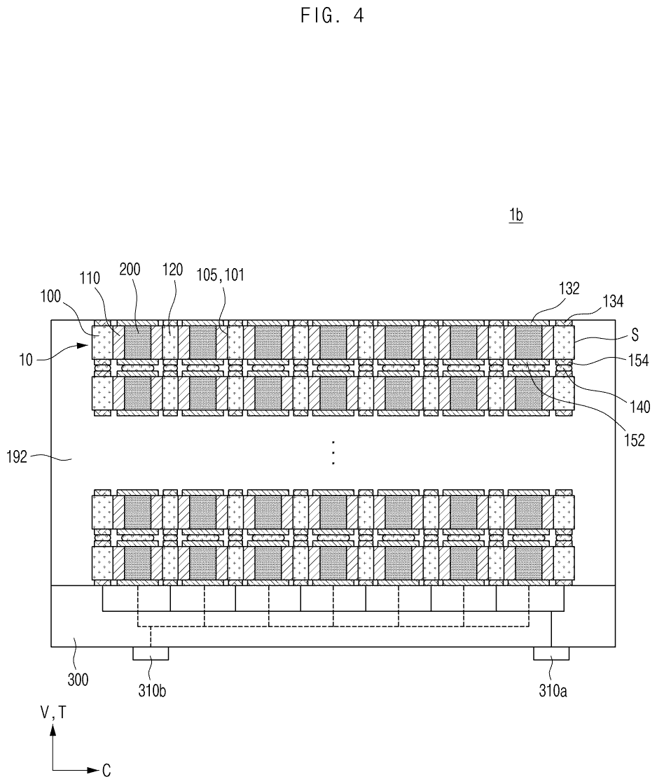

FIG. 4 is a side cross-sectional view illustrating an isotope capacitor 1b according to an aspect of the present disclosure.

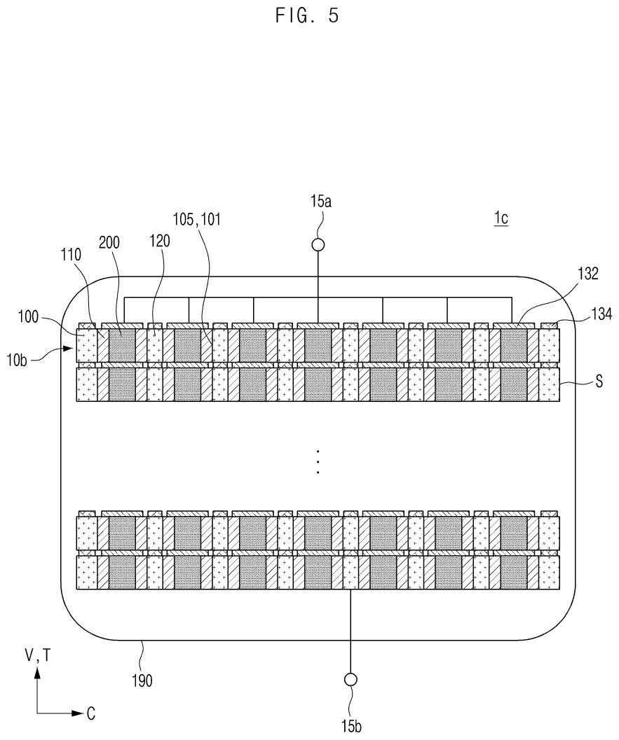

The isotope capacitor 1b shown in FIG. 4 is substantially the same as the isotope capacitor 1 described with reference to FIG. 1a through FIG. 3, but differs in that the plurality of isotope capacitor sheets 10 are enclosed by a molding member 192 and in that the plurality of isotope capacitor sheets 10 are mounted on the controller chip 300. Accordingly, the following description will focus on these differences and omit description of the commonalities. It should be understood that any of the isotope capacitors 1, 1a of FIGS. 1a to 3b as well as any one of the isotope capacitors of FIGS. 5 to 9, which are described below, may also be mounted on a controller chip 300 and/or embedded in a molding member 192.

Referring to FIG. 4, the plurality of isotope capacitor sheets 10 is mounted on a controller chip 300. In some aspects, the controller chip 300 may include a power management integrated circuit (PMIC) that outputs electrical energy generated by the plurality of stacked isotope capacitor sheets 10 to an external load according to predetermined rules.

The plurality of isotope capacitor sheets 10 may be molded by a molding resin 192. The molding resin 192 may include, for example, an epoxy molding compound (EMC). In one or more aspects, the molding resin 192 may be between the housing 190 and the plurality of isotope capacitor sheets 10.

The first upper electrode 132 and the second upper electrode 134 of the topmost isotope capacitor sheet 10 may serve as dummy electrodes when the plurality of isotope capacitor sheets 10 are electrically connected to the controller chip 300 through the first lower electrode 152 and second lower electrode 154 on the lowermost isotope capacitor sheet as shown in FIG. 4. In some aspects, at least one of the first upper electrode 132 and the second upper electrode 134 of the topmost isotope capacitor sheet 10 may extend through the molding resin 192 and may be exposed to the outside.

In other aspects, the first upper electrode 132 and the second upper electrode 134 of the topmost of isotope capacitor sheet 10 may be completely covered by the molding resin 192. In some aspects, the upper surface of the topmost isotope capacitor sheet of the plurality of isotope capacitor sheets 10 lacks both the first upper electrode 132 and the second upper electrode 134 and is instead covered by a passivation layer or by the molding member 192 or by both the passivation layer and the molding member 192.

The electrical energy generated by the plurality of isotope capacitor sheets 10 may be supplied to an external load via external terminals 310a, 310b provided on the controller chip 300. In FIG. 4, the plurality of isotope capacitor sheets 10 are shown mounted on the upper part of the controller chip 300, but aspects of the present disclosure are not limited to this configuration.

FIG. 5 is a side cross-sectional view illustrating an isotope capacitor 1c according to another aspect of the present disclosure.

Referring to FIG. 5, the isotope capacitor 1c may include a plurality of stacked isotope capacitor sheets 10b stacked in the vertical direction V, or the substrate thickness direction T.

The isotope capacitor sheet 10b differs from the isotope capacitor sheet 10 of FIG. 1a in that the first lower electrode 152, the second lower electrode 154, and the connector 140 are omitted from the isotope capacitor sheet 10b. Accordingly, the following discussion will focus on these differences and omit discussion of the commonalities.

The isotope capacitor sheet 10b includes a first upper electrode 132 and a second upper electrode 134 on the upper surface of the substrate 100. In some aspects, each the isotope capacitor sheets 10b of the plurality of stacked isotope capacitor sheets 10b may all have the same type of semiconductor die.

The first upper electrode 132 and the second upper electrode 134 of a first isotope capacitor sheet 10b may be in direct contact with the bottom surfaces of the second material 110 and the first material 120, respectively, of an isotope capacitor sheet 10b above and adjacent to the first isotope capacitor sheet 10b. In other words, on an isotope capacitor sheet 10b, first upper electrodes 132 and second upper electrodes 134 may only be provided on the first—or top major—surface of the substrate 100, and the second—or bottom major—surface of a substrate 100 of the isotope capacitor sheet 10b may be in electrical contact with the electrodes 132, 134 on the first—or top major—surface of the substrate 100 of an isotope capacitor sheet 10b arranged directly thereunder.

The isotope capacitor 1c can be configured more compactly since the first lower electrodes 152, the second lower electrodes 154, and the connector 140 are omitted, thereby increasing the energy density.

In some aspects, the second material 110 of an isotope capacitor sheet 10b and the first material 120 of an adjacent isotope capacitor sheets may be in direct contact with each other, omitting any electrodes between adjacent isotope capacitor sheets within the stack.

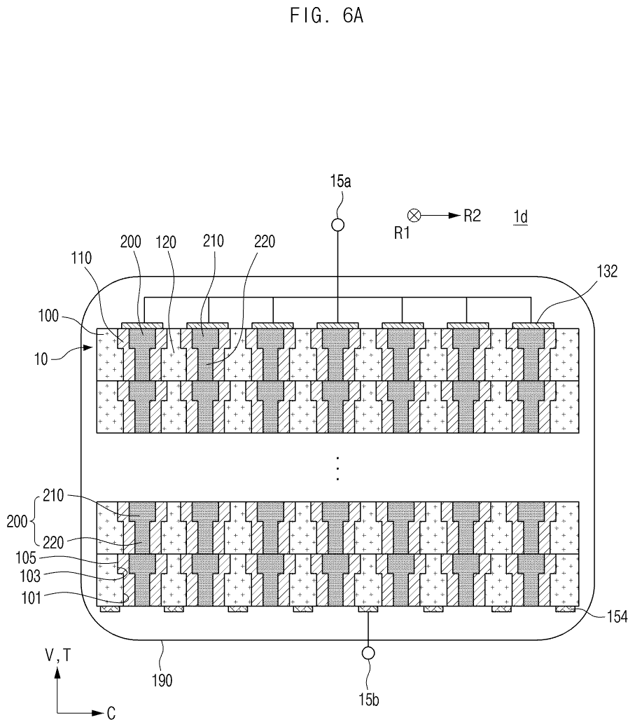

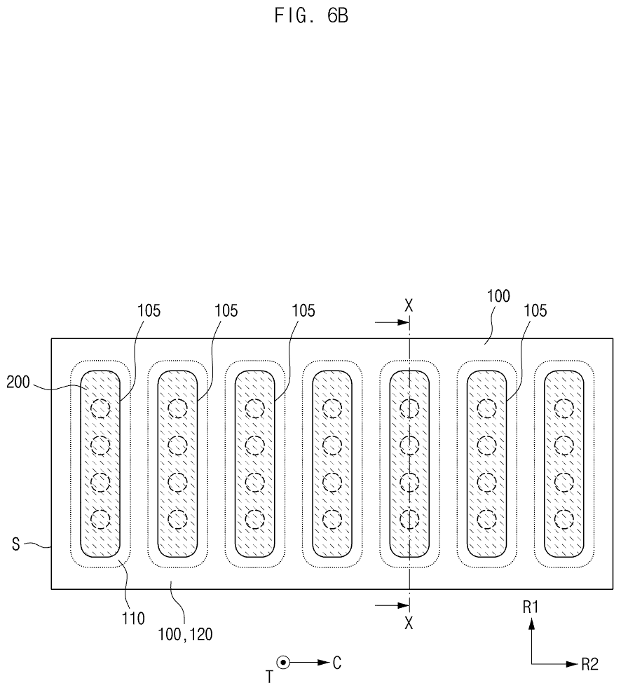

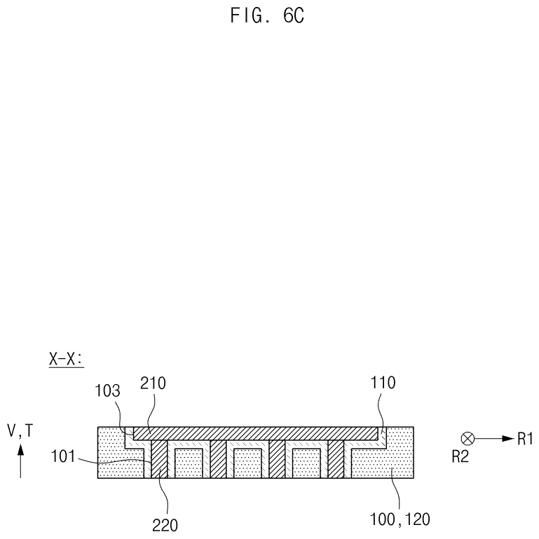

FIG. 6a is a side cross-sectional view illustrating an isotope capacitor 1d according to another aspect of the present disclosure. FIG. 6b is a plan view of an isotope capacitor sheet of the isotope capacitor of FIG. 6a. FIG. 6c is a cross-sectional view along line X-X of FIG. 6b.

Referring to FIG. 6a, the isotope capacitor 1d may include a plurality of stacked isotope capacitor sheets 10c.

The isotope capacitor sheets 10c shown in FIGS. 6a, 6b, and 6c differ from those shown in FIG. 1a mainly in the configuration of a cavity 105 in the substrate 100. As exemplarily shown in FIG. 6a, the cavity 105 has a shape of a stepped recess. The cavity 105 may comprise a trench or recess 103 formed in the first surface of the substrate 100. In addition, one or more through-holes 101 may extend between a bottom of the trench or recess 103 and the second surface of the substrate 100.

The isotope capacitor sheet 10c may include a trench 103 extending along the upper surface of the substrate 100 and a through-hole 101 extending from a bottom surface of the trench 103 to a lower surface of the substrate 100. As exemplarily shown in FIG. 6b, the trench 103 may extend longitudinally in the first direction R1, and the through-hole 101 may extend vertically from a bottom surface of the trench 103 in the substrate thickness direction T. The trench 103 may have a width extending in the second direction R2. In one or more aspects, a length of the trench 103 in the first direction R1 may be greater than the width of the trench 103. The first direction R1 is perpendicular to the second direction R2. In some aspects, a plurality of through-holes 101 may be arranged along the first direction R1 within a single trench 103, as exemplarily shown in FIGS. 6b and 6c.

A radiation source 200 may be positioned inside the trench 103 and the plurality of through-holes 101. The radiation source 200 may include a first portion 210 extending in the first direction R1 of the trench 103 and disposed within the trench 103. Further, the radiation source 200 may include a second portion 220 disposed within the through-hole 101 extending from the bottom of the trench 103 to the second—or bottom major—surface of the substrate 100.

A width of the first portion 210 of the radiation source 200 in the second direction R2 may be larger than the width of the second portion 220 of the radiation source 200 in the second direction R2. The width in the second direction R2 of the second material 110 corresponding to the first portion 210 of the radiation source 200 may be larger than the width in the second direction R2 of the second material 110 corresponding to the second portion 220 of the radiation source.

The second material 110 of the substrate 100 may have a substantially constant thickness from the surface of the radiation source 200.

In one or more aspects, the isotope capacitor sheets 10c may be stacked without an intervening layer between adjacent isotope capacitor sheets 10c. In such aspects, the radiation source 200 of an isotope capacitor sheet 10c may contact a radiation source 200 of an adjacent isotope capacitor sheet 10c, the second material 110 of the substrate 100 of an isotope capacitor sheet 10c may contact the second material 110 of the substrate 100 of an adjacent isotope capacitor sheet 10c, and the first material 120 of the substrate 100 of an isotope capacitor sheet 10c may contact the first material 120 of the substrate 100 of an adjacent isotope capacitor sheet 10c. The uppermost isotope capacitor sheet 10c in the vertical direction V may comprise the first upper electrode 132 or the second upper electrode 134 and the lowest isotope capacitor sheet 10c in the vertical direction V may comprise the first lower electrode 152 or the second lower electrode 154. In aspects where the uppermost isotope capacitor sheet comprises the first upper electrode 132, the lowest isotope capacitor sheet may comprise the second lower electrode 154, and in aspects where the uppermost isotope capacitor sheet comprises the second upper electrode 134, the lowest isotope capacitor sheet may comprise the first lower electrode 152. Omitting the electrodes and connectors from the space between adjacent isotope capacitor sheets 10c may improve the energy density of the isotope capacitor 1d. Furthermore, it should be understood that electrodes and connectors may be omitted from isotope capacitors according to other aspects of the present disclosure to improve the energy density of the isotope capacitors.

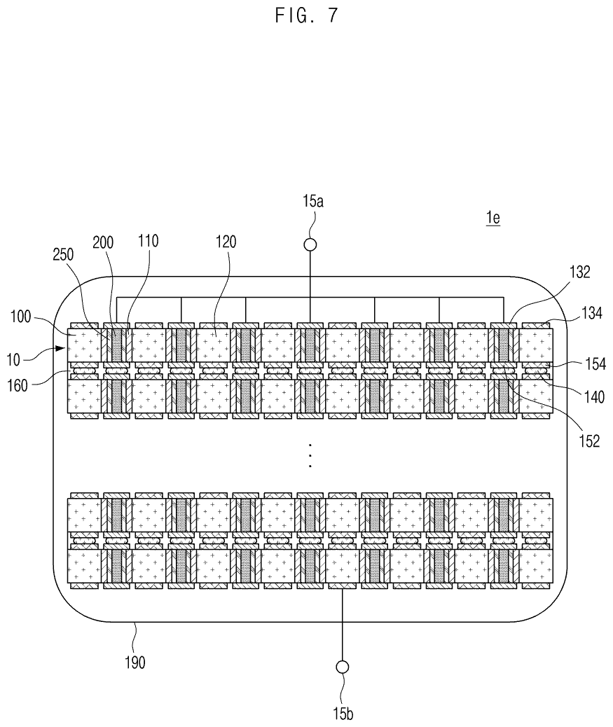

FIG. 7 is a side cross-sectional view illustrating an isotope capacitor 1e according to an aspect of the present disclosure. The isotope capacitor 1e of FIG. 7 differs in that it further includes a photon generating layer 210 around the radiation source 200 of the isotope capacitor 1 shown in FIG. 1a, and this difference will be discussed below.

Referring to FIG. 7, the photon generating layer 210 may be any layer of material capable of emitting photons in response to radiation, such as alpha rays, emitted from the radiation source 200. In some aspects, the radiation source 200 may be a material that emits alpha rays. Such materials have been described with reference to FIG. 1a and will not be described in detail herein.

In one or more aspects, the photon generating layer 210 may comprise materials such as, but not limited to, Ba₂Ca(BO₃)₂, BaHfO₃, BaI₂:Ce, BeO, BaF₂, BaMgF₄, Cs₂LiLuCi₆:Ce, K₂YF₅, KCaF₃, YI₃:Ce, or the like. Various examples materials that may be included in the photon generating layer 210 are disclosed in the Berkeley Lab Inorganic Scintillator Laboratory found at: https://scintillator.lbl.gov/inorganic-scintillator-library/.

The photon generating layer 210 may emit photons in response to alpha rays incident from the radiation source 200. Photons generated by the photon generating layer 210 may be incident on the interface between the second material 110 and the first material 120, and electrical energy may be generated by the photons.

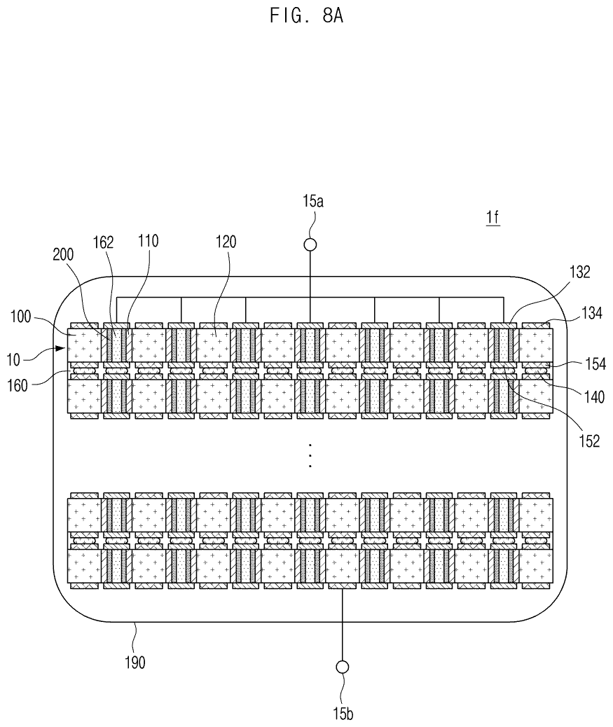

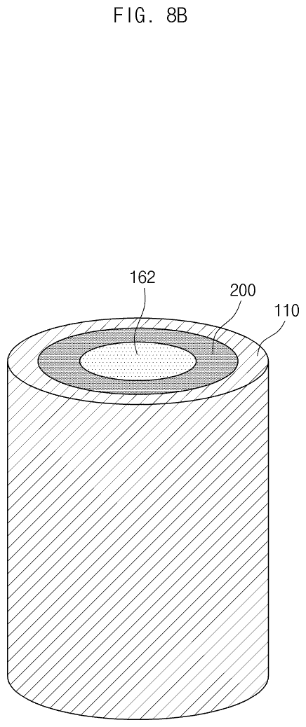

FIG. 8a is a side cross-sectional view of an isotope capacitor 1F according to an aspect of the present disclosure. FIG. 8b is an enlarged perspective view of the second material 110, the radiation source 200, and the insulating layer 162 of the isotope capacitor 1f. The isotope capacitor 1f shown in FIGS. 8a and 8b differs from the isotope capacitor 1 in FIG. 1a in that the radiation source 200 of the isotope capacitor 1 has an annular shape, and the following discussion will focus on this difference.

Referring to FIGS. 8a and 8b, the radiation source 200 may have a hollow tube shape with a central opening. The radiation source 200 may have a substantially uniform thickness and extend along a surface of first region 110. In some aspects, the central opening of the radiation source 200 may be filled by the insulating layer 162. In some other aspects, the central portion may be filled by the substrate 100 or a semiconductor layer derived therefrom. In yet other aspects, the central portion may be filled with or may include a material serving to reflect the radiation (e.g., alpha rays, beta rays, etc.) emitted from the radiation source 200. In that manner, such material may redirect incident radiation outwardly where it may better be absorbed by the substrate 100 having the interface between the second material 110 and the first material 120 (e.g., in the form of a p-n junction). Such reflective material is not limited to any particular material. In some examples, the material may be or may include material having radiation reflecting properties, such as copper, silver, or aluminum metal. In other examples, the material may be or may include material having radiation shielding properties, such as polymers like polyethylene, polypropylene, ethylene propylene copolymer, ethylene methacrylate copolymer, or polyethylene terephthalate.

In examples where the radiation source 200 has a hollow tube shape (e.g., filled with an insulating layer 162 in its interior), the amount of radiation source required to form the radiation source 200 may be reduced. Since radiation sources are expensive, by forming the annular radiation source 200 in this manner, the isotope capacitor 1f can be manufactured inexpensively.

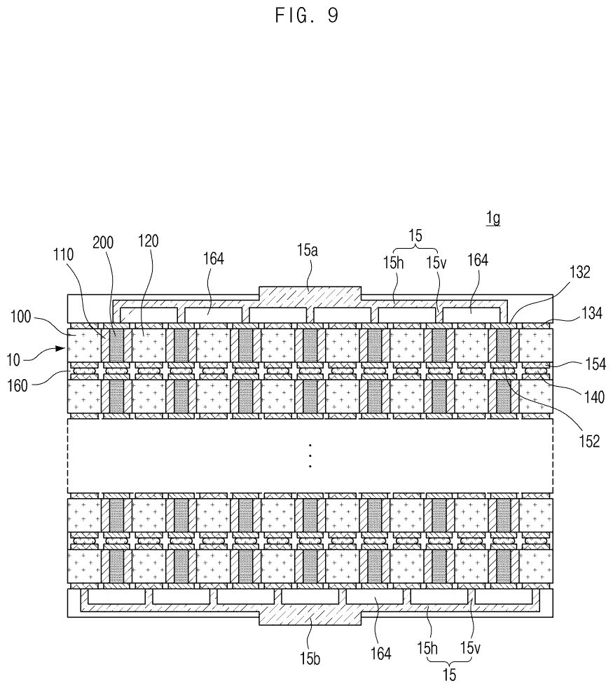

FIG. 9 is a side cross-sectional view of an isotope capacitor 1g according to another aspect of the present disclosure. The isotope capacitor 1g shown in FIG. 9 differs from the isotope capacitor 1 shown in FIG. 1a in that the external electrodes 15a, 15b of the isotope capacitor 1 are further specified, and the following discussion will focus on these differences.

Referring to FIG. 9, the isotope capacitor 1g includes a first external electrode 15a and a second external electrode 15b for supplying electrical energy to an external load.

The first external electrode 15a includes conductive members 15 extending within an insulator 164 to connect the first upper electrodes 132 of the isotope capacitor sheet 10. The conductive members 15 are electrically connected only to the first upper electrodes 132.

In some aspects, the conductive members 15 may comprise one or more first conductive members 15h and one or more second conductive members 15v. The first conductive members 15h and the second conductive members 15v may extend in different directions within the insulator 164. The second conductive members 15v may electrically connect the first conductive members 15h and the first upper electrodes 132. The first conductive members 15h may be physically and/or electrically connected to the first external electrode 15a. In some aspects, the first conductive members 15h may extend in a horizontal direction and the second conductive members 15v may extend in a vertical direction, but aspects of the present disclosure are not limited thereto.

In some aspects, the second upper electrode 134 of the isotope capacitor sheet 10 closest to the first external electrode 15a may be omitted.

The second external electrode 15b may also be electrically connected to the isotope capacitor sheets 10 in a similar manner to the first external electrode 15a. A person of ordinary skill in the art will be able to conceive of the wiring connections between the second external electrode 15b and the isotope capacitor sheets 10 by reference to the wiring connections between the first external electrode 15a and the isotope capacitor sheets 10 described above.

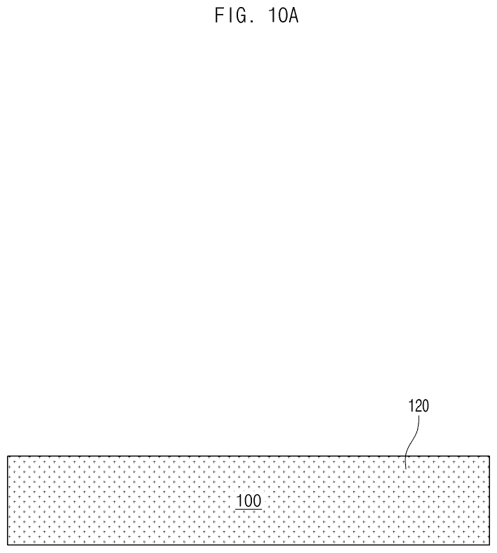

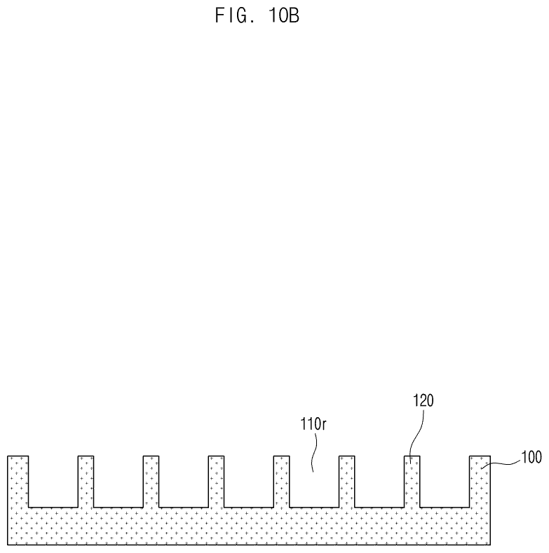

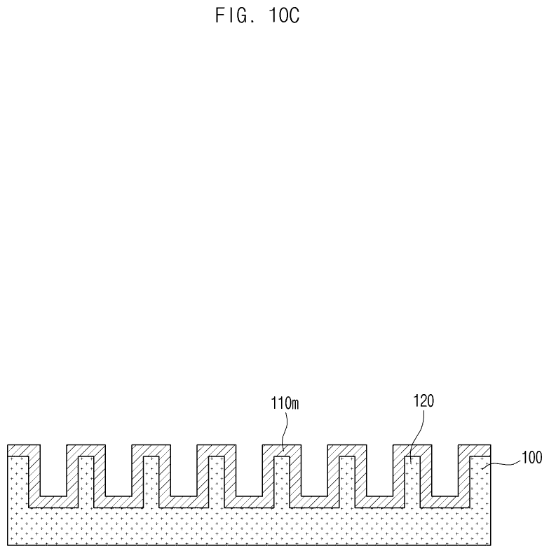

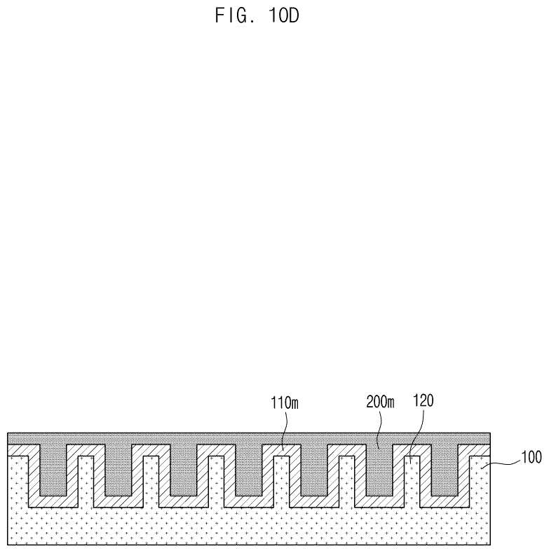

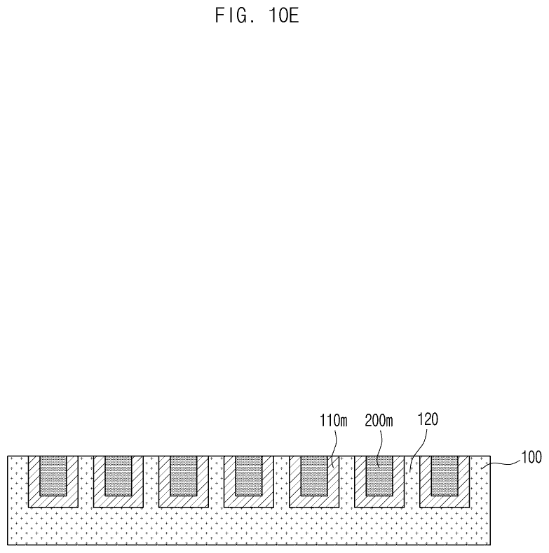

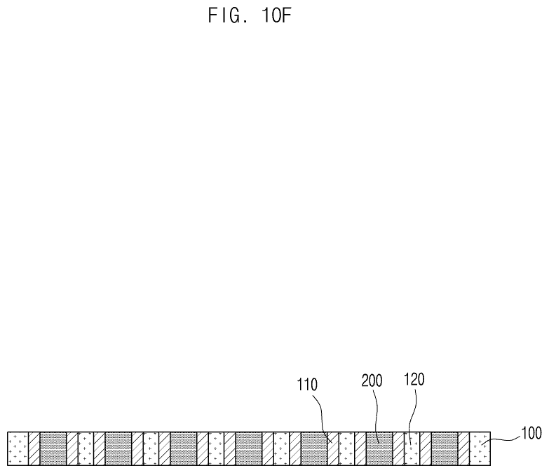

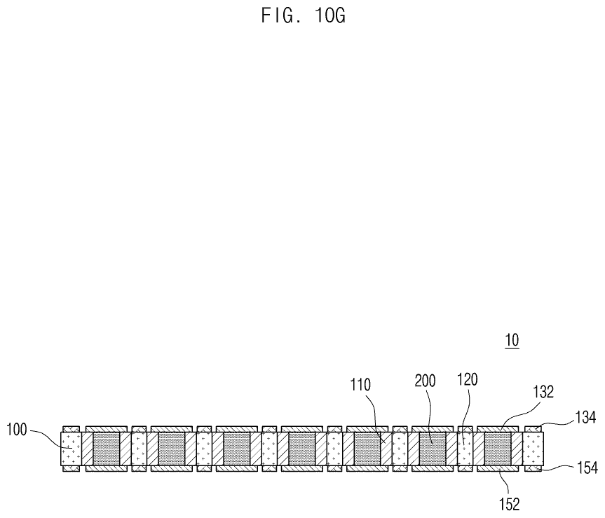

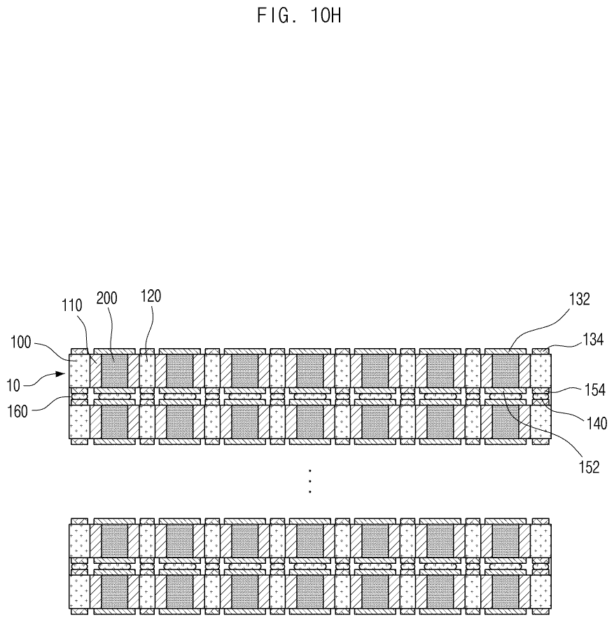

FIGS. 10a to 10h are side views illustrating sequential steps of a method of manufacturing an isotope capacitor 1 according to an aspect of the present disclosure.

Referring to FIG. 10a, a substrate 100 comprising a first material 120 is provided. The first material 120 can include, for example, a material having an energy bandgap of about 2.5 eV or greater. In some aspects, the first material 120 may include a diamond substrate, a SiC substrate, a sapphire substrate, or a combination thereof.

At least a portion of the first material 120 may be doped with a dopant. The dopant may be a dopant of a desired conductivity, and may have an opposite conductivity to the dopant doped in the metal oxide material layer 200m described later.

The dopant may be doped throughout the entirety of the first material 120, or it may be locally doped to form wells. In some aspects, there may be regions within the interior of the first material 120 that are not doped with a particular conductivity.

Referring to FIG. 10b, a plurality of recesses 100r can be formed in the first material 120.

The recess 100r may be formed, for example, by deep reactive ion etching (DRIE). However, aspects of the present disclosure are not limited thereto. The recess 100r may be in the form of a hole or a trench extending in the substrate thickness direction in FIG. 10b.

The side walls of the recess 100R include the a doped region of the first material 120.

The aspect ratio of the recess 100r can be determined by considering a desired thickness of the second material layer 110, the film properties of the radiation source 200, and the like.

Referring to FIG. 10c, a metal oxide material layer 110m may be formed with a predetermined thickness on the interior of the recess 100r and on the upper surface of the first material 120.

The metal oxide material layer 110m may be formed by any known method. For example, the metal oxide material layer 110m may be formed by methods such as physical vapor deposition (PVD), chemical vapor deposition (CVD), or atomic layer deposition (ALD). However, aspects of the present disclosure are not limited to these. One of ordinary skill in the art will be able to select an appropriate deposition method based on the type of material to be deposited, the nature of the precursor or source, the step coverage required, and the like.

The metal oxide material layer 110m may be made of the same material as the second material 110 described above, which will not be described in detail herein. As previously described, the metal oxide material layer 110m may be doped with dopants of the desired conductive type. The doped region of the first material 120 and the metal oxide material layer 110m may form a p-n junction at least at the sidewalls of the recess 110r.

The metal oxide material layer 110m may be formed conformally in the interior of the recess 110r. As described herein, when the metal oxide material layer 110m is formed conformally, the metal oxide material layer 110m is formed with the shape of the surface of the first material 120. For example, the metal oxide material layer 110m is formed with a substantially constant thickness, so that the shape of the metal oxide material layer 110m conforms to the shape of the surface of the first material 120 beneath it. Thus, the recess 110r has an unfilled space even after the formation of the metal oxide material layer 110m.

Referring to FIG. 10d, a radiation source material layer 200m is formed on the unfilled portion of the recess 110R and on the upper surface of the metal oxide material layer 110m.

The radiation source material layer 200m may be formed by any known method. For example, the radiation source material layer 200m may be formed by methods such as PVD, CVD, or ALD. However, aspects of the present disclosure are not limited to these methods. A person of ordinary skill in the art will be able to select an appropriate deposition method, considering the type of material to be deposited, the nature of the precursor or source, the stepwise applicability required, and the like.

The radiation source material layer 200m may be made of the same material as the radiation source 200 described above, which will not be described in detail herein.

The radiation source material layer 200m may fill the space in the recess 110r that remains after the deposition of the metal oxide material layer 110m.

Referring to FIG. 10e, at least a portion of the radiation source material layer 200m and the metal oxide material layer 110m may be removed so that an upper surface of the first material 120 is exposed.

In some aspects, portions of the radiation source material layer 200m and the metal oxide material layer 110m on the upper surface of the first material 120 may be removed.

The radiation source material layer 200m and the metal oxide material layer 110m may be partially removed and leveled by dry etching, wet etching, and/or chemical mechanical polishing (CMP).

Referring to FIG. 10f, at least a portion of the lower part of the first material 120 may be removed. The lower surface of the first material 120 may be removed until the lower surface of the radiation source 200 is exposed.

The lower part of the first material 120 may be removed and leveled by dry etching, wet etching, and/or CMP. As the lower surface of the first material 120 is removed, the lower part of the metal oxide material layer 110m and the radiation source material layer 200m may also be partially removed. By partially removing the lower part of the first material 120, the radiation source 200 is allowed to penetrate the first material 120.

Referring to FIG. 10g, a first upper electrode 132 and a first lower electrode 152 may be formed on the upper and lower parts of the second material layer 110, respectively, and a second upper electrode 134 and a second lower electrode 154 may be formed on the upper and lower parts of the first material 120, respectively, to form the isotope capacitor sheet 10.

The electrodes 132, 152, 134, 154 may be formed, for example, by electroplating or electroless plating. In some aspects, only some of the electrodes 132, 152, 134, 154 may be formed.

Referring to FIG. 10h, the isotope capacitor sheets 10 may be repeatedly stacked. The stacked isotope capacitor sheets 10 may be electrically connected to each other by a connector 140.

In some aspects, an insulator 160 may be positioned between two neighboring isotope capacitor sheets 10. The insulator 160 has been described above with reference to FIG. 1 and will not be described in detail herein.

The plurality of stacked isotope capacitor sheets 10 are then electrically connected and housed within the housing 190 to obtain an isotope capacitor 1 as shown in FIG. 1.

Although aspects of the present disclosure have been described in detail above, one of ordinary skill in the art to which the present disclosure belongs will be able to make many modifications to aspects of the present disclosure without departing from the spirit and scope of the present disclosure as defined in the appended claims. Accordingly, future modifications of aspects of the present disclosure will not depart from the technology of the present disclosure.

1. An isotope capacitor comprising:
a plurality of isotope capacitor sheets that are stacked in a first direction; and
a first external electrode having a first polarity; and
a second external electrode having a second polarity;
wherein each isotope capacitor sheet of the plurality of isotope capacitor sheets comprises:
a substrate comprising a first material and a second material; and
a radiation source,
wherein the first material is a non-conductor or a semiconductor,
wherein the second material has an electrical conductivity greater than an electrical conductivity of the first material,
wherein the substrate comprises an interface between the first material and the second material,
wherein the radiation source extends through at least a portion of the substrate in the first direction,
wherein the radiation source is spaced apart from the interface between the first material and the second material,
wherein the first external electrode is electrically connected to the plurality of isotope capacitor sheets,
wherein the second external electrode is electrically connected to the plurality of isotope capacitor sheets, and
wherein the first external electrode and the second external electrode are configured to transfer electrical energy generated by the plurality of isotope capacitor sheets to an external load.

2. An isotope capacitor comprising:
a plurality of isotope capacitor sheets that are stacked in a first direction;
a first external electrode having a first polarity; and
a second external electrode having a second polarity,
wherein each isotope capacitor sheet of the plurality of isotope capacitor sheets comprises:
a substrate comprising a first material and a second material; and
a radiation source,
wherein the radiation source extends through at least a portion of the substrate in the first direction,
wherein the first material comprises a semiconductor material,
wherein the second material comprises a metal oxide,
wherein the second material has a bandgap that is less than a bandgap of the first material,
wherein the second material of the substrate is between the radiation source and the first material of the substrate,
wherein the first external electrode is electrically connected to the plurality of isotope capacitor sheets,
wherein the second external electrode is electrically connected to the plurality of isotope capacitor sheets,
wherein the first external electrode and the second external electrode are configured to transfer electrical energy generated by the plurality of stacked isotope capacitor sheets to an external load.

3. The isotope capacitor of claim 2, wherein
the metal oxide comprises AMO₃, wherein:
A is at least one element selected from the group consisting of La, Ba, Sr, and K, and
M is at least one element selected from the group consisting of Al, In, Ga, Ti, Sn, Hf, Ta, and Zr.

4. The isotope capacitor of claim 2, wherein
the metal oxide comprises one or more of BaSnO₃, BaHfO₃, BaZrO₃, BaHf₁₋ₓTiₓO₃ (where 0<x<1), Ba₁₋ₓLaₓSnO₃ (where 0<x<1), Bi₄Ge₃O₁₂, Al₂O₃, Y₂O₃, La₂O₃, Ga₂O₃, Bi₂O₃, ZrO₂, HfO₂, Ta₂O₅, TiO₂, LaInO₃, LaGaO₃, SrZrO₃, SrHfO₃, SrTaO₇, LaIn₁₋ₓGaₓO₃ (where 0<x<1), LaGaO₃, SrTiO₃, KTaO₃, HfSiO₄, Ta₃Ti₂Oₓ, or LaAlO₃.

5. The isotope capacitor of claim 2, wherein
the metal oxide comprises BaSnO₃.

6. The isotope capacitor of claim 2, wherein
the semiconductor material comprises a diamond material, a SiC material, a GaN material, a Bi₂O₃/GeO₂ material, a Sm₂O₃/Bi₂O₃/GeO₂ material, a Sm₂O₃/Bi₂O₃/B₂O₃ material, a Sm₂O₃/Bi₂O₃/GeO₂/B₂O₃ material, a sapphire material, or a combination thereof.

7. The isotope capacitor of claim 2, wherein
the radiation source is within a through-hole extending into the semiconductor substrate.

8. The isotope capacitor of claim 7, wherein
the semiconductor substrate includes a plurality of through-holes, and the radiation source is within each of the plurality of through-holes.

9. The isotope capacitor of claim 8, wherein
each through-hole of the plurality of through-holes is disposed in the semiconductor substrate at the vertex of an equilateral triangle in a plane normal to the first direction.

10. The isotope capacitor of claim 7, wherein
the second material surrounds a side of the radiation source that extends through the at least a portion of the substrate in the first direction.

11. The isotope capacitor of claim 2, wherein
the radiation source is within a slit extending into the semiconductor substrate.

12. The isotope capacitor of claim 11, wherein
the substrate includes a plurality of slits, and the radiation source is within each of the plurality of slits.

13. The isotope capacitor of claim 11, wherein
the radiation source has an elongated side that extends through the at least a portion of the substate in the first direction and the second material faces the elongated side of the radiation source.

14. The isotope capacitor of claim 2, wherein
each isotope capacitor sheet of the plurality of isotope capacitor sheets is substantially identical.

15. The isotope capacitor of claim 2, wherein
the plurality of isotope capacitor sheets are electrically connected to each other by solder balls.

16. The isotope capacitor of claim 2, further including
a controller chip, wherein the plurality of isotope capacitor sheets are mounted on the controller chip, and wherein the controller chip is configured to control the transfer of electrical energy generated by the plurality of isotope capacitor sheets to an external load.

17. The isotope capacitor of claim 16, wherein
the plurality of isotope capacitor sheets are at least partially enclosed by a molding resin.

18. The isotope capacitor of claim 17, wherein
the plurality of isotope capacitor sheets comprises at least one dummy electrode that extends through the molding resin.

19. The stack-type capacitor of claim 2, wherein
each isotope capacitor sheet of the plurality of isotope capacitor sheets comprises a first electrode on the second material and a second electrode on the first material, and
wherein the first electrode and the second electrode of a first isotope capacitor sheet of the plurality of isotope capacitor sheets are in contact with the second material and the first material, respectively, of a second isotope capacitor sheet above the first isotope capacitor sheet.

20. The isotope capacitor of claim 2,
wherein the radiation source comprises:
a trench extending into a first surface of the substrate; and
one or more through-holes extending from a bottom surface of the trench to a second surface of the substrate opposite the first surface of the semiconductor substrate;
wherein a first portion of the radiation source is within the trench and a second portion of the radiation source is within the one or more through-holes.

21. The isotope capacitor of claim 20, wherein
a width of the trench is greater than a width of each of the one or more through-holes.

22. The isotope capacitor of claim 20, wherein
a width of the first portion of the radiation source and the second material of the substrate corresponding to the first portion of the radiation source is greater than a width of the second portion of the radiation source and the second material of the substrate corresponding to the second portion of the radiation source.

23. The isotope capacitor of claim 2, wherein
the metal oxide has a bandgap energy of 2.7 eV or greater.
